(19) United States
(12) Patent Application Publication
(10) Pub. No.: US 2024/0421222 A1
(43) Pub. Date: Dec. 19, 2024

(54) SEMICONDUCTOR DEVICE AND METHOD FOR FORMING THE SAME

(71) Applicant: Fujian Jinhua Integrated Circuit Co., Ltd., Quanzhou City (CN)

(72) Inventors: Chia-Wei Wu, Quanzhou City (CN); Yu- Cheng Tung, Quanzhou City (CN)

(21) Appl. No.: 18/376,424

(22) Filed: Oct. 3, 2023

(30) Foreign Application Priority Data
Jun. 14, 2023 (CN) 202310703573.X
Jun. 14, 2023 (CN) 202321513752.9

(51) Int. Cl. H01L 29/78; H01L 29/423; H01L 29/43; H01L 29/66

(52) U.S. Cl. CPC H01L 29/7827; H01L 29/42364; H01L 29/437; H01L 29/66666

(57) ABSTRACT

A semiconductor device includes a substrate. A first dielectric layer, a second dielectric layer, and a third dielectric layer are sequentially disposed on the substrate. A source structure is formed in the first dielectric layer. A drain structure is formed in the third dielectric layer. A channel structure extends through the second dielectric layer and directly contacts the source structure and the drain structure. A gate structure is disposed at two sides of the channel structure. The gate structure includes a conductive layer and a gate dielectric layer. The gate dielectric layer is along sidewalls and a bottom surface of the conductive layer, and is interposed between the conductive layer and the channel structure and the second dielectric layer.

### BACKGROUND OF THE INVENTION

### 1. Field of the Invention

The present invention relates to a semiconductor device and a method for forming the same. More particularly, the present invention relates to a semiconductor device having a vertical channel structure and a method for forming the same.

### 2. Description of the Prior Art

As the semiconductor manufacturing technology continues to progress, generation by generation, the designs of the integrated circuits have become more and more delicate and complex. To fulfill the demands for advanced product innovation, the geometric dimensions of the electrical components of the functional circuit blocks of a chip are decreased to achieve a higher device density. Due to the limitations in further shrinkage of the conventional planar type metal-oxide-semiconductor (MOS) transistors, novel three-dimensional or non-planar type transistors have been proposed in the field to replace conventional planar type transistors to achieve a smaller chip size and improved performance.

### SUMMARY OF THE INVENTION

One objective of the present invention is to provide a semiconductor device having a vertical channel structure and a method for forming the same.

One embodiment of the present invention provides a semiconductor device, which includes a substrate, a first dielectric layer, a second dielectric layer, and a third dielectric layer sequentially disposed on the substrate, a source structure in the first dielectric layer, a drain structure in the third dielectric layer, a channel structure extending through the second dielectric layer and directly contacting the source structure and the drain structure, and a gate structure disposed at two sides of the channel structure. The gate structure comprises a conductive layer and a gate dielectric layer along sidewalls and a bottom surface of the conductive layer and interposed between the conductive layer and the channel structure and the second dielectric layer.

Another embodiment of the present invention provides a method for forming a semiconductor device including the steps of providing a substrate, forming a first dielectric layer on the substrate and a source structure in the first dielectric layer, forming a second dielectric layer on the first dielectric layer, forming a channel structure and a sacrificial layer along a sidewall of the channel structure, wherein the channel structure extends through the second dielectric layer, and a bottom surface of the channel structure is in direct contact with the source structure, replacing the sacrificial layer with a gate structure, and forming a third dielectric layer on the second dielectric layer and a drain structure in the third dielectric layer, wherein a top surface of the channel structure is in direct contact with the drain structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. Relative dimensions and proportions of parts of the drawings have been shown exaggerated or reduced in size, for the sake of clarity and convenience in the drawings. The same reference signs are generally used to refer to corresponding or similar features in modified and different embodiments.

FIG. 1 to FIG. 9 are schematic drawings illustrating the steps for forming a semiconductor device according to an embodiment of the present invention.

FIG. 10 is a schematic cross-sectional view of a semiconductor device according to another embodiment of the present invention.

FIG. 11 and FIG. 12 are schematic cross-sectional views of a semiconductor device according to another embodiment of the present invention.

### DETAILED DESCRIPTION

To provide a better understanding of the present invention to those of ordinary skill in the art, several exemplary embodiments of the present invention will be detailed as follows, with reference to the accompanying drawings using numbered elements to elaborate the contents and effects to be achieved. Other embodiments may be utilized and that structural, logical and electrical changes may be made without departing from the spirit and scope of the present invention.

The drawings in this disclosure only depict a part of the semiconductor device. The numbers and scales of the components shown in the drawings are for illustration only, and are not intended to limit the scope of the present invention. The scales may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

FIG. 1 to FIG. 9 are schematic drawings illustrating the steps for forming a semiconductor device according to an embodiment of the present invention. As shown in FIG. 1, a substrate 10A is provided. A first dielectric layer 10 is formed on the substrate 10A. A source structure 12 is formed in the first dielectric layer 10. A second dielectric layer 20 is formed on the first dielectric layer 10 and covers the source structure 12. The first dielectric layer 10, the source structure 12 and the second dielectric layer 20 may be formed by performing well known deposition, etching, and damascene processes, which will not be described herein for brevity. In some embodiments, other interlayer dielectric layers may be provided between the first dielectric layer 10 and the substrate 10A. The first dielectric layer 10 and the interlayer dielectric layers may include other electrical components (not shown).

The substrate 10A may be any substrate suitable for manufacturing semiconductor devices. The substrate 10A may be a silicon substrate, an epitaxial silicon substrate, a silicon germanium (SiGe) substrate, a silicon carbide (SiC) substrate, or a silicon-on-insulator (SOI) substrate, but is not limited thereto. The substrate 10A may include electrical components and integrated circuit structures (not shown) formed therein or thereon.

The first dielectric layer 10 and the second dielectric layer 20 respectively include a dielectric material, such as silicon oxide (SiO₂), silicon nitride (SiN), silicon oxynitride (SiON), silicon carbide nitride (SiCN), nitrogen doped silicon carbide (NDC), a low-k dielectric material such as fluorinated silica glass (FSG), carbon silicon oxide (SiCOH), spin-on silicon glass, porous low-k dielectric material, organic polymer dielectric material, or a combination of the above materials, but are not limited thereto. In some embodiments, the first dielectric layer 10 includes silicon oxide (SiO₂).

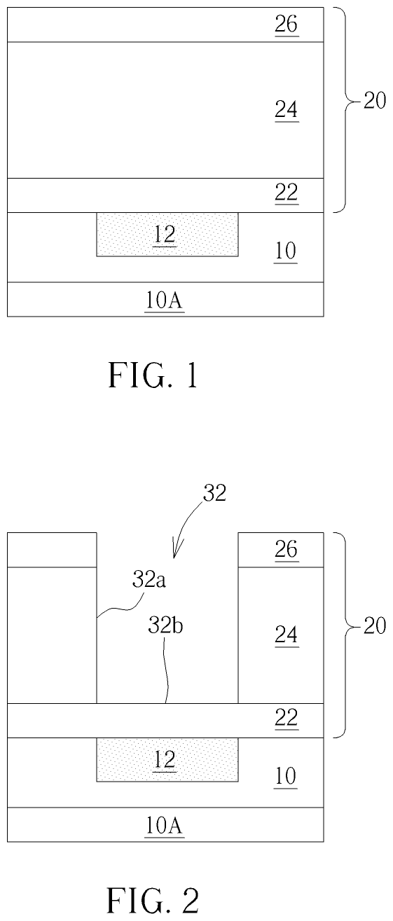

In some embodiments, the second dielectric layer 20 may include multi dielectric layers to increase the process window for subsequent manufacturing processes. For example, the second dielectric layer 20 may include, from bottom to top, an etching stop layer 22, a dielectric material layer 24, and a pad layer 26. The etching stop layer 22 and the dielectric material layer 24 are made of different materials to provide etching selectivity during subsequent etching process to control the depth of the first opening 32 (shown in FIG. 2). In some embodiments, the dielectric material layer 24 and the pad layer 26 are made of silicon oxide (SiO₂), and the etching stop layer 22 is made of silicon nitride (SiN). In some embodiments, the dielectric material layer 24 and the pad layer 26 have different film densities, and the boundary between the dielectric material layer 24 and the pad layer 26 may be distinguished by an electron microscope or using any suitable technique.

The source structure 12 includes a conductive material, such as a conductive metal material, a conductive non-metal material, or a combination thereof. The conductive metal material suitable for the source structure 12 may include tungsten (W), copper (Cu), aluminum (Al), titanium (Ti), tantalum (Ta), a compound, an alloy or a composite layer of the above materials, but is not limited thereto. The conductive non-metal material suitable for the source structure 12 may include amorphous silicon, poly silicon, or doped silicon, but is not limited thereto. In some embodiments, the source structure 12 includes tungsten (W).

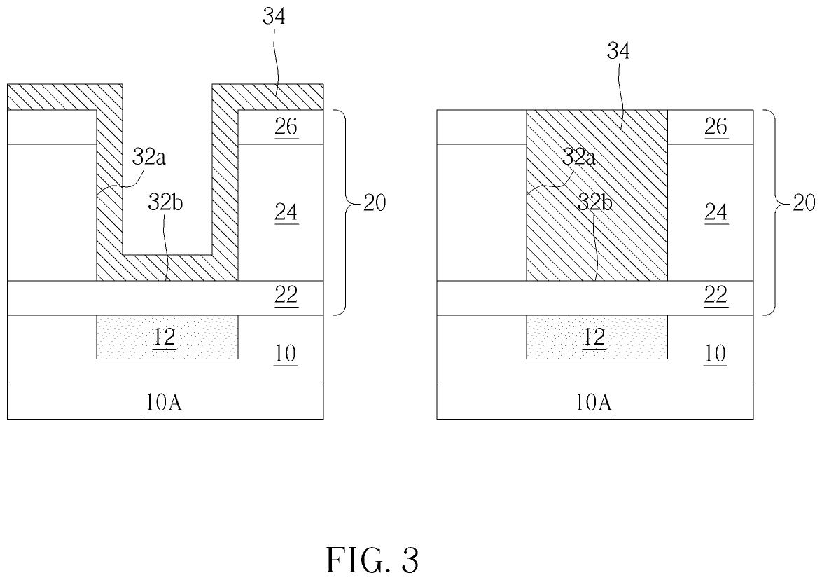

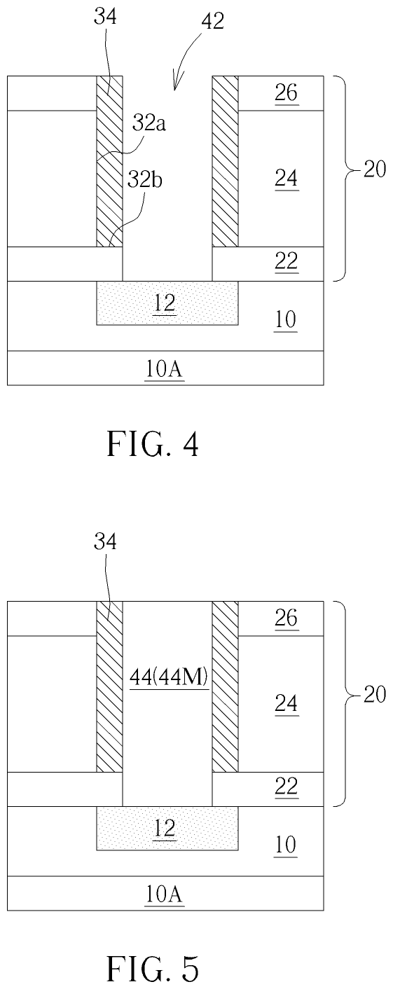

Please refer to FIG. 2, the left portion of FIG. 3, and FIG. 4. Subsequently, an etching process such as a reactive ion etching (RIE) process is performed to form a first opening 32 in the second dielectric layer 20. The first opening 32 extends through the pad layer 26 and the dielectric material layer 24 until exposing the etching stop layer 22, and is vertically aligned to the source structure 12 in the first dielectric layer 10. Next, a deposition process such as chemical vapor deposition (CVD) process, physical vapor deposition (PVD) process, atomic layer deposition (ALD) process, or any suitable deposition process is performed to form a sacrificial layer 34 on the second dielectric layer 20. The sacrificial layer 34 conformally covers the upper surface of the second dielectric layer 20 and the sidewalls 32a and bottom surface 32b of the first opening 32. After that, another etching process such as a reactive ion etching (RIE) process is performed to etch and remove the sacrificial layer 34 on the bottom surface 32b of the first opening 32 and the etching stop layer 22 directly under the first opening 32, thereby forming a second opening 42 that exposes a portion of the source structure 12. As shown in FIG. 4, the portions of the sacrificial layer 34 on sidewalls 32a of the first opening 32 are remained with a pre-determined thickness by reducing the lateral etching rate of the etching process. The sidewalls 32a of the first opening 32 are completely covered by the remaining portions of the sacrificial layer 34 and are not exposed form the second opening 42. The material of the sacrificial layer 34 is different from the material of the channel material layer 44M (shown in FIG. 5) and the material of the dielectric material layer 24 of the second dielectric layer 20 to allow a selective removal of the sacrificial layer 34 in a subsequent process. In some embodiments, the sacrificial layer 34 may include silicon oxide (SiO2), silicon nitride (SiN), or silicon oxynitride (SiON), but is not limited thereto.

Please refer to the right portion of FIG. 3 and FIG. 4. In an alternative embodiment, the sacrificial layer 34 may be formed to fill up the first opening 32, and a patterned mask layer (not shown) may be formed to cover the second dielectric layer 20 and the portions of the sacrificial layer 34 on the sidewalls 32a of the first opening 32. The portion of the sacrificial layer 34 exposed from the patterned mask layer is then etched and removed by a subsequent etching process such as a reactive ion etching (RIE) process, thereby forming a second opening 34 that extends through the sacrificial layer 34 in the first opening 32 and the etching stop layer 22 under the first opening 32 to expose the source structure 12.

Please refer to FIG. 5. Subsequently, a channel material layer 44M is formed on the second dielectric layer 20 and fills the second opening 42. A removal process such as a chemical mechanical polishing (CMP) process is performed to remove the channel material layer 44M outside the second opening 42, thereby obtaining a channel structure 44 in the second opening 42. The channel material layer 44M (the channel structure 44) includes a semiconductor material such as a silicon-based semiconductor material or a metal-oxide semiconductor material. The silicon-based semiconductor material may include amorphous silicon, poly silicon, or doped silicon, or a combination thereof, but is not limited thereto. The metal-oxide semiconductor material may include indium-gallium-zinc oxide (IGZO), zinc oxide (ZnO), tin oxide (SnO), indium-zinc oxide (IZO), gallium-zinc oxide (GZO), zinc-tin oxide (ZTO), indium-gallium oxide (IGO), indium-tin-zinc oxide (ITZO), or indium-tin oxide (ITO), or a combination thereof, but is not limited thereto. In some embodiments, the channel material layer 44M (the channel structure 44) includes poly silicon.

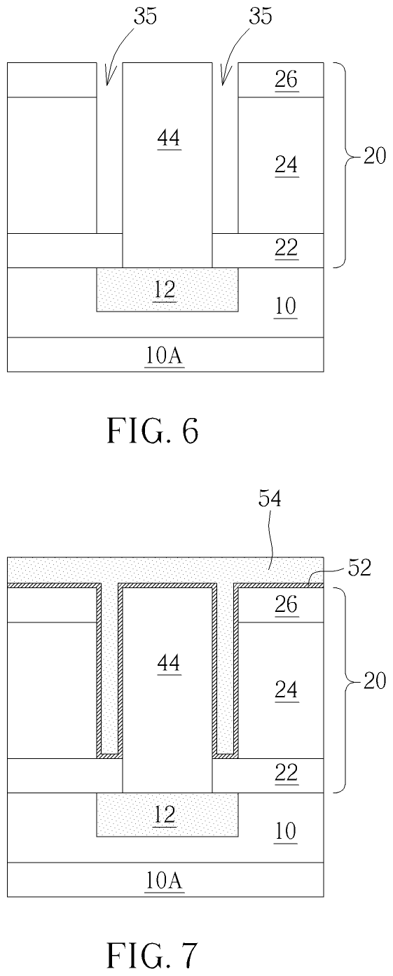

Please refer to FIG. 6. Subsequently, an etching process such as a wet etching process is performed to selectively remove the remaining portions of the sacrificial layer 34, thereby forming gate openings 35 at two sides of the channel structure 44, between the channel structure 44 and the second dielectric layer 20, and exposing sidewalls of the channel structure 44.

Please refer to FIG. 7. Subsequently, a gate dielectric layer 52 is formed on the second dielectric layer 20 and along the sidewalls and bottom surfaces of the gate openings 35. A conductive layer 54 is formed on the gate dielectric layer 52 and fills the gate openings 35. The gate dielectric layer 52 and the conductive layer 54 may be respectively formed by any suitable deposition process such as chemical vapor deposition (CVD) process, physical vapor deposition (PVD) process, or atomic layer deposition (ALD) process, but is not limited thereto. The portions of the etching stop layer 22, the dielectric material layer 24, and the pad layer 26 exposed from the gate openings 35 are covered by the gate dielectric layer 52 and physically separated from the conductive layer 54. The gate dielectric layer 52 may include a single or multiple dielectric layers made of silicon oxide (SiO₂), silicon nitride (SiN), silicon oxynitride (SiON), silicon carbide nitride (SiCN), high-k dielectric materials such as hafnium oxide (HfO₂), hafnium silicon oxide (HfSiO₄), hafnium silicon oxynitride (HfSiON), aluminum oxide (AlO), zinc oxide (ZrO₂), titanium oxide (TiO₂), other metal oxide dielectrics, or a combination thereof, but are not limited thereto. The conductive layer 54 may include a conductive metal material, a conductive non-metal material, or a combination thereof. The conductive metal material suitable for the conductive layer 54 may include tungsten (W), copper (Cu), aluminum (Al), titanium (Ti), tantalum (Ta), a compound, an alloy or a composite layer of the above materials, but is not limited thereto. The conductive non-metal material suitable for the conductive layer 54 may include amorphous silicon, poly silicon, or doped silicon, but is not limited thereto. In some embodiments, the conductive layer 54 includes tungsten (W). In some embodiments, the conductive layer 54 may include a void 70.

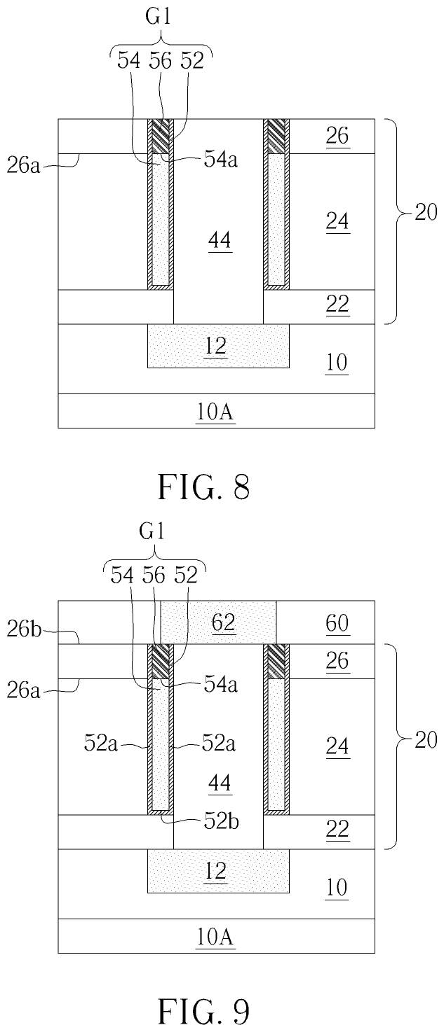

Please refer to FIG. 8. Subsequently, a removal process such as a chemical mechanical polishing (CMP) process is performed to remove the conductive layer 54 and the gate dielectric layer 52 outside the gate openings 35 until the upper surface of the pad layer 26 is exposed. After that, an etching back process is performed to further recess the conductive layer 54 in the gate openings 35 to expose upper portions of the gate openings 35. The top surface 54a of the conductive layer 54 may be recessed to be approximately at a same height as the lower surface 26a of the pad layer 26, or lower than the lower surface 26a of the pad layer 26. After that, a deposition process such as chemical vapor deposition (CVD) process, physical vapor deposition (PVD) process, atomic layer deposition (ALD) process, or any suitable deposition process may be performed to form an insulating material (not shown) on the pad layer 26. A removal process such as a chemical mechanical polishing (CMP) process is then performed to remove the portion of the insulating material outside the gate openings 35, thereby forming an insulating cap layer 56 directly on the conductive layer 54 and filling the upper portion each of the gate openings 35. After this step, a gate structure G1 in each of the gate openings 35 is obtained. The insulating cap layer 56 includes a dielectric material such as silicon oxide (SiO₂), silicon nitride (SiN), silicon oxynitride (SiON), silicon carbide nitride (SiCN), a high-k dielectric material, or a combination thereof, but is not limited thereto. In some embodiments, the insulating cap layer 56 includes silicon nitride (SiN). The pad layer 26 may be used as a buffer layer or an etching stop layer during the above chemical mechanical polishing process or etching back process to control the second dielectric layer 20 to have a desired thickness and surface flatness and ensure that there is no remaining conductive layer 54 outside the gate openings 35.

Please refer to FIG. 9. Subsequently, a third dielectric layer 60 is formed on the second dielectric layer 20. A drain structure 62 is formed in the third dielectric layer 60. The third dielectric layer 60 and the drain structure 62 may be formed by performing well known deposition, etching, and damascene processes, which will not be described herein for brevity. The third dielectric layer 60 includes a dielectric material, such as silicon oxide (SiO₂), silicon nitride (SiN), silicon oxynitride (SiON), silicon carbide nitride (SiCN), nitrogen doped silicon carbide (NDC), a low-k dielectric material such as fluorinated silica glass (FSG), carbon silicon oxide (SiCOH), spin-on silicon glass, porous low-k dielectric material, organic polymer dielectric material, or a combination of the above materials, but are not limited thereto. In some embodiments, the third dielectric layer 60 includes silicon oxide (SiO₂). The drain structure 62 includes a conductive material, such as a conductive metal material, a conductive non-metal material, or a combination thereof. The conductive metal material suitable for the drain structure 62 may include tungsten (W), copper (Cu), aluminum (Al), titanium (Ti), tantalum (Ta), a compound, an alloy or a composite layer of the above materials, but is not limited thereto. The conductive non-metal material suitable for the drain structure 62 may include amorphous silicon, poly silicon, or doped silicon, but is not limited thereto. In some embodiments, the drain structure 62 includes tungsten (W).

After finishing the above manufacturing steps, the semiconductor device according to the embodiment is obtained. As shown in FIG. 9, the semiconductor device includes a substrate 10, and a first dielectric layer 10, a second dielectric layer 20, and a third dielectric layer 60 are sequentially disposed on the substrate 10A. A channel structure 44 is formed in the second dielectric layer 20 and extends vertically through the second dielectric layer 20. The bottom surface of the channel structure 44 is in direct contact with a source structure 12 in the first dielectric layer 10. The top surface of the channel structure 44 is in direct contact with a drain structure 62 in the third dielectric layer 60. A gate structure G1 is disposed at two sides of the channel structure 44, along sidewalls of the channel structure 44. The gate structure G1 includes a conductive layer 54 and a gate dielectric layer 52. The gate dielectric layer 52 extends along the sidewalls and bottom surface of the conductive layer 54 to physically separate the conductive layer 54 from the channel structure 44 and the second dielectric layer 20. The region of the channel structure 44 overlapped by the gate structure G1 is a vertical channel region of the semiconductor device.

In some embodiments, the gate dielectric layer 52 has a U-shaped cross-sectional profile, including vertical portions 52a along the sidewalls of the conductive layer 54 and a lateral portion 52b along the bottom surface of the conductive layer 54. In some embodiments, the top surfaces of the vertical portions 52a are approximately flush with the upper surface (that is, the upper surface 26b of the pad layer 26) of the second dielectric layer 20.

In some embodiments, the gate structure G1 further includes an insulating cap layer 56 disposed on the conductive layer 54. In some embodiments, the top surface of the insulating cap layer 56 is approximately flush with the upper surface (that is, the upper surface 26b of the pad layer 26) of the second dielectric layer 20. The drain structure 62 may partially cover and directly contact the top surface of the insulating cap layer 56.

In some embodiments, the insulating cap layer 56 is physically separated from the channel structure 44 and the second dielectric layer 20 by the vertical portions 52a of the gate dielectric layer 52. The insulating cap layer 56 is not in direct contact with the channel structure 44 and the second dielectric layer 20.

In some embodiments, the second dielectric layer 20 includes a multi-layer structure. The second dielectric layer 20 may include, from bottom to top, an etch stop layer 22, a dielectric material layer 24, and a pad layer 26. The bottom surface of the gate structure G1 is preferably on the etch stop layer 22 and at a height higher than the bottom surface of the channel structure 44. The top surface 54a of the conductive layer 54 is approximately at a same height as the lower surface 26a of the pad layer 26, or is slightly lower than the lower surface 26a of the pad layer 26.

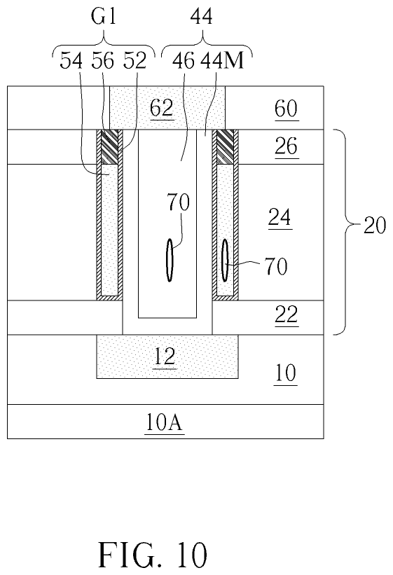

Please refer to FIG. 10, which shows a schematic cross-sectional view of a semiconductor device according to another embodiment of the present invention. Most of the semiconductor device shown in FIG. 10 is similar to the semiconductor device shown in FIG. 9, and the similar features will not be described herein for brevity. A major difference between the semiconductor device shown in FIG. 10 and the semiconductor device shown in FIG. 9 is that, the channel structure 44 of the semiconductor device shown in FIG. 10 includes the channel material layer 44M and a dielectric layer 46 on the channel material layer 44M. The channel material layer 44M is conformal to the sidewalls and bottom surface of the second opening 42, and does not fill up the second opening 42. The remaining space of the second opening 42 is filled by the dielectric layer 46. As shown in FIG. 10, the channel material layer 44M may include a U-shaped cross-sectional profile. In some embodiments, the dielectric layer 46 may include a void 70.

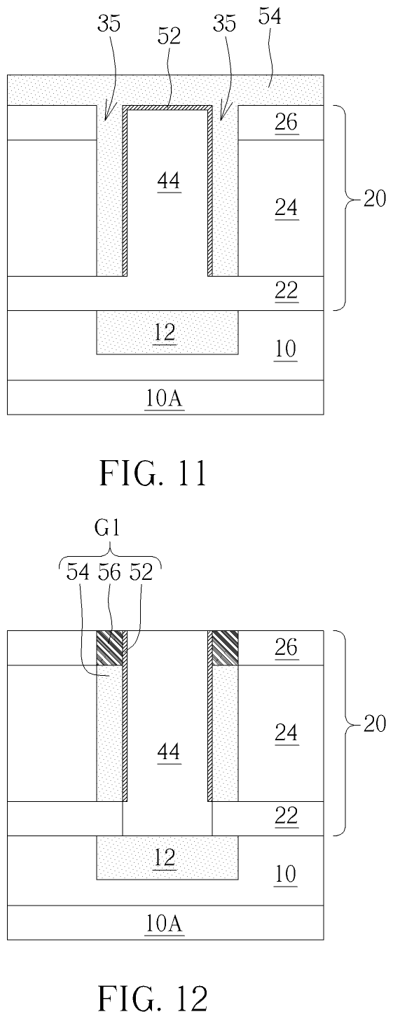

Please refer to FIG. 11 and FIG. 12. FIG. 11 is a schematic cross-sectional view of a semiconductor device after forming a gate dielectric layer 52 and a conductive layer 54 according to another embodiment of the present invention. FIG. 12 is a schematic cross-sectional view of the semiconductor device shown in FIG. 11 after forming the gate structure G1. The gate dielectric layer 52 shown in FIG. 11 may be formed by performing an oxidation process (such as in-situ steam generation oxidation process) to oxidize the exposed surface of the channel structure 44. The gate dielectric layer 52 is formed along the top surface and sidewalls of the channel structure 44, and does not formed on the exposed surfaces of the etching stop layer 22, the dielectric material layer 24, and the pad layer 26. The material of the gate dielectric layer 52 is an oxide of the channel structure 44, such as silicon oxide (SiO2). After that, a deposition process such as chemical vapor deposition (CVD) process, physical vapor deposition (PVD) process, atomic layer deposition (ALD) process, or any suitable deposition process is performed to form the conductive layer 54 on the gate dielectric layer 52 and filling the gate openings 35.

Subsequently, as shown in FIG. 12, a removal process such as a chemical mechanical polishing (CMP) process is performed to remove the conductive layer 54 outside the gate openings 35 until exposing the upper surface of the pad layer 26. After that, an etching back process is performed to further recess the conductive layer 54 in the gate openings 35 to expose upper portions of the gate openings 35. The top surface 54a of the conductive layer 54 may be recessed to be approximately at a same height as the lower surface 26a of the pad layer 26, or lower than the lower surface 26a of the pad layer 26. Afterward, a deposition process such as chemical vapor deposition (CVD) process, physical vapor deposition (PVD) process, atomic layer deposition (ALD) process, or any suitable deposition process may be performed to form an insulating material (not shown) on the pad layer 26. A removal process such as a chemical mechanical polishing (CMP) process is then performed to remove the portion of the insulating material outside the gate openings 35, thereby obtaining the gate structure G1 with an insulating cap layer 56 directly on the conductive layer 54 and filling the upper portion each of the gate openings 35. The gate dielectric layer 52 formed on the top surface of the channel structure 44 may be removed during the above manufacturing process, such that the gate dielectric layer 52 of the gate structure G1 shown in FIG. 2 may have a straight-line shaped cross-sectional profile.

In conclusion, the present invention provides a semiconductor device which has a vertical channel structure and may be miniaturized to achieve a higher device density and smaller chip size that is hard for conventional semiconductor device with planar channel structure. The present invention also provides a method to form the semiconductor device, in which the vertical channel structure and the gate structure of the semiconductor device are formed by forming an opening in the dielectric layer, forming the channel structure in the opening and a sacrificial layer at two sides of the channel structure, and replacing the sacrificial layer with the gate structure. The method provided by the present invention may obtain the vertical channel structure and gate structure in simplified steps, and a higher process window and an improved manufacturability of the semiconductor device may be achieved. The manufacturing cost and process time may be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first dielectric layer, a second dielectric layer, and a third dielectric layer sequentially disposed on the substrate;
a source structure in the first dielectric layer;
a drain structure in the third dielectric layer;
a channel structure extending through the second dielectric layer and directly contacting the source structure and the drain structure; and
a gate structure disposed at two sides of the channel structure, wherein the gate structure comprises:
a conductive layer; and
a gate dielectric layer along sidewalls and a bottom surface of the conductive layer and interposed between the conductive layer and the channel structure and the second dielectric layer.

2. The semiconductor device according to claim 1, wherein the gate dielectric layer has a U-shaped cross-sectional profile.

3. The semiconductor device according to claim 1, wherein the gate dielectric layer comprises:
vertical portions along the sidewalls of the conductive layer; and
a lateral portion along the bottom surface of the conductive layer, wherein top surfaces of the vertical portions are flush with a top surface of the second dielectric layer.

4. The semiconductor device according to claim 1, wherein the gate structure further comprises:
an insulating cap layer disposed on the conductive layer, wherein a top surface of the insulating cap layer is flush with the top surface of the second dielectric layer.

5. The semiconductor device according to claim 4, wherein the drain structure is in direct contact with the top surface of the insulating cap layer.

6. The semiconductor device according to claim 4, wherein the gate dielectric layer is interposed between the insulating cap layer and the channel structure and the second dielectric layer.

7. The semiconductor device according to claim 1, wherein the second dielectric layer comprises:
an etching stop layer;
a dielectric material layer on the etching stop layer; and
a pad layer on the dielectric material layer, wherein the gate structure is above the etching stop layer and through the dielectric material layer and the pad layer.

8. The semiconductor device according to claim 7, wherein a top surface of the conductive layer is at a same height as a bottom surface of the pad layer.

9. The semiconductor device according to claim 7, wherein a top surface of the conductive layer is lower than a bottom surface of the pad layer.

10. The semiconductor device according to claim 1, wherein the conductive layer, the source structure, and the drain structure comprise tungsten, the channel structure comprises poly silicon.

11. A method for forming a semiconductor device, comprising:
providing a substrate;
forming a first dielectric layer on the substrate and a source structure in the first dielectric layer;
forming a second dielectric layer on the first dielectric layer;
forming a channel structure and a sacrificial layer along a sidewall of the channel structure, wherein the channel structure extends through the second dielectric layer, and a bottom surface of the channel structure is in direct contact with the source structure;
replacing the sacrificial layer with a gate structure; and
forming a third dielectric layer on the second dielectric layer and a drain structure in the third dielectric layer, wherein a top surface of the channel structure is in direct contact with the drain structure.

12. The method for forming a semiconductor device according to claim 11, wherein the step of forming the second dielectric layer comprises:
forming an etching stop layer;
forming a dielectric material layer on the etching stop layer; and
forming a pad layer on the dielectric material layer, wherein the sacrificial layer is on the etching stop layer.

13. The method for forming a semiconductor device according to claim 12, wherein the step of forming the channel structure and the sacrificial layer comprises:
forming a first opening through the pad layer and the dielectric material layer;
forming the sacrificial layer on sidewalls and a bottom surface of the first opening;
forming a second opening by etching the sacrificial layer on the bottom surface of the first opening and the etching stop layer until exposing the source structure; and
forming the channel structure in the second opening.

14. The method for forming a semiconductor device according to claim 12, wherein the step of forming the channel structure and the sacrificial layer comprises:
forming a first opening through the pad layer and the dielectric material layer;
forming the sacrificial layer filling up the first opening;
forming a second opening through the sacrificial layer and the etching stop layer and exposing the source structure; and
forming the channel structure in the second opening.

15. The method for forming a semiconductor device according to claim 11, wherein the step of replacing the sacrificial layer with the gate structure comprises:
removing the sacrificial layer to form a gate opening that exposes a sidewall of the channel structure;
forming a gate dielectric layer along the gate opening; and
forming a conductive layer on the gate dielectric layer.

16. The method for forming a semiconductor device according to claim 15, wherein the step of replacing the sacrificial layer with the gate structure further comprises:
etching back the conductive layer; and
forming an insulating cap layer on the conductive layer and filling the gate opening.

17. The method for forming a semiconductor device according to claim 15, wherein the gate dielectric layer has a U-shaped cross-sectional profile.

18. The method for forming a semiconductor device according to claim 15, wherein the gate dielectric layer comprises:
vertical portions along the sidewalls of the gate opening; and
a lateral portion along a bottom surface of the gate opening, wherein top surfaces of the vertical portions are flush with a top surface of the second dielectric layer.

19. The method for forming a semiconductor device according to claim 15, wherein the conductive layer comprises a void.

20. The method for forming a semiconductor device according to claim 15, wherein the conductive layer, the source structure, and the drain structure comprise tungsten, the channel structure comprises poly silicon.
